(19) United States
(12) Patent Application Publication
(10) Pub. No.: US 2026/0304676 A1
(43) Pub. Date: Oct. 1, 2026

(54) Information Technology Cabinet System Having Angular Rail Mounts

(71) Applicant: Panduit Corp., Tinley Park, IL (US)

(72) Inventors: Ryan N. Murphy, Monee, IL (US); Eric Beaupre, Palos Park, IL (US); Surendra Chitti Babu, Naperville, IL (US)

(73) Assignee: Panduit Corp., Tinley Park, IL (US)

(21) Appl. No.: 19/535,139

(22) Filed: Feb. 10, 2026

Related U.S. Application Data
(60) Provisional application No. 63/779,576, filed on Mar. 28, 2025.

(51) Int. Cl. H05K 7/14

(52) U.S. Cl. CPC H05K 7/1489

(57) ABSTRACT

A cabinet system includes a cabinet frame, an equipment rail, and an angular rail mount. The cabinet frame includes a plurality of rails defining an interior space to house computing equipment. The equipment rail is connected to the cabinet frame in the interior space and extends parallel to a longitudinal axis of the cabinet frame. The angular rail mount includes a first fastening member connected to the equipment rail and a second fastening member adapted to connect to a cabinet distribution equipment. The second fastening member is angularly offset from the first fastening member to have a virtual plane defined by the second fastening member intersecting virtual orthogonal planes of the cabinet frame.

### CROSS-REFERENCE TO RELATED APPLICATIONS

This application claims benefit to U.S. Provisional Patent Application No. 63/779,576, filed on Mar. 28, 2025, the entirety of which is hereby incorporated by reference herein.

### TECHNICAL FIELD

The present disclosure is generally direct towards a cabinet system for storing information technology (IT) equipment.

### BACKGROUND

The statements in this section merely provide background information related to the present disclosure and may not constitute prior art.

Data center information technology (IT) equipment is typically stacked vertically in cabinet systems defined in rack units and can be air cooled using perimeter cooling units (e.g., a computer room air conditioner (CRAC) or computer room air handler (CRAH)). With increasing rack power density, created by continuously increasing CPU/GPU thermal design power (TDP), air cooling is being replaced with direct-to-chip (DTC) liquid-cooling, which has a higher cooling capacity than air. DTC liquid-cooled racks require the installation of a minimum of two in-rack manifolds. The in-rack manifolds distribute cooling water from the facility water system to the IT equipment. One manifold is used for the supply water and the other is used for the return water.

### SUMMARY

This section provides a general summary of the disclosure and is not a comprehensive disclosure of its full scope or all of its features.

In some aspects, the present disclosure is directed to a cabinet system that includes a cabinet frame, an equipment rail, and an angular rail mount. The cabinet frame includes a plurality of rails defining an interior space to house computing equipment. The equipment rail is connected (e.g., coupled) to the cabinet frame in the interior space and extends parallel to a longitudinal axis of the cabinet frame (e.g., parallel to the height of the cabinet frame). The angular rail mount includes a first fastening member connected to the equipment rail (e-rail) and a second fastening member adapted to connect to a cabinet distribution equipment. The second fastening member is angularly offset from the first fastening member to have a virtual plane defined by the second fastening member intersecting virtual orthogonal planes of the cabinet frame.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

In order that the disclosure may be well understood, there will now be described various forms thereof, given by way of example, reference being made to the accompanying drawings, in which:

FIG. 1 is an example cabinet system having an angular rail mount;

FIG. 2A is a top view of the cabinet system of FIG. 1;

FIG. 2B is an enlarged view of enclosure B of FIG. 2A;

FIG. 3 illustrates an angular offset of a cabinet distribution equipment provided by the angular rail mount;

FIG. 4A illustrates an e-rail assembly of the cabinet system of FIG. 1;

FIG. 4B is an exploded view of the e-rail assembly of FIG. 4A;

FIG. 5 illustrates enlarged view of the e-rail assembly at the angular rail mount;

FIG. 6 illustrates a portion of the e-rail;

FIG. 7A is a perspective view of the angular rail mount in a first embodiment;

FIG. 7B is a top view of the angular rail mount of FIG. 7A;

FIG. 7C is a front view of the angular rail mount of FIG. 7A;

FIG. 8 is an example e-rail assembly in a second embodiment having multiple cabinet distribution equipment;

FIG. 9 is an exploded view of the e-rail assembly of FIG. 8

FIG. 10 is an example e-rail assembly in a third embodiment having cabinet distribution equipment rotatable at the ends of the device;

FIG. 11 is an exploded view of the e-rail assembly of FIG. 10;

FIG. 12A is a perspective view of an e-rail assembly in a fourth embodiment having an angular rail mount with multiple keyholes;

FIG. 12B is a top view of the e-rail assembly of FIG. 12A;

FIG. 13A is a perspective view of an e-rail assembly in a fifth embodiment having end plates for providing rotatable operation of the cabinet distribution equipment;

FIG. 13B is a bottom view of the e-rail assembly of FIG. 13A;

FIG. 14 is perspective view of a top plate of the e-rail assembly of FIGS. 13A and 13B;

FIG. 15 is a perspective view of an e-rail assembly in a sixth embodiment having a static angular rail mount;

FIG. 16 is perspective view of the static angular rail mount;

FIG. 17 is an exploded view of the static angular rail mount of FIG. 16;

FIG. 18 is a top view of a static angular rail mount with no cabinet distribution equipment;

FIG. 19 is a top view of a static angular rail mount with cabinet distribution equipment;

FIG. 20 is top view of a static angular rail mount having a long lateral extension;

FIG. 21A is a perspective view of an e-rail assembly in a seventh embodiment having a top position angular rail mount;

FIG. 21B is an exploded view of the e-rail assembly of FIG. 21A;

FIG. 22A is a perspective view of the angular rail mount of FIG. 21A;

FIG. 22B is an exploded view of the angular rail mount of FIG. 22B;

FIG. 23 is a perspective view of an e-rail assembly in an eighth embodiment having an angular rail mount with independently controlled cabinet distribution equipment;

FIG. 24A is a perspective view of the angular rail mount of FIG. 23;

FIG. 24B is an exploded view of the angular rail mount of FIG. 24A;

FIG. 25 is a perspective view of an e-rail assembly in a ninth embodiment;

FIG. 26 is a rear view of the e-rail assembly of FIG. 25;

FIG. 27 is a top view of the e-rail assembly of FIG. 25; and

FIG. 28 is a top view of an e-rail assembly in a tenth embodiment.

### DETAILED DESCRIPTION

The following description is merely exemplary in nature and is not intended to limit the present disclosure, application, or uses. It should be understood that throughout the drawings, corresponding reference numerals indicate like or corresponding parts and features.

In some aspects, the present disclosure is directed to a cabinet system for storing computing equipment used in IT systems, such as, but not limited to data centers, servers, among others. The cabinet system may include a cabinet frame, an equipment rail, and an angular rail mount. The cabinet frame includes a plurality of rails defining an interior space to house computing equipment. The equipment rail is connected to the cabinet frame in the interior space and extends parallel to a longitudinal axis of the cabinet frame (e.g., extends parallel to a height of the cabinet frame). The angular rail mount is adapted to connect (e.g., configured to couple) a cabinet distribution equipment to the equipment rail at an angle. In some aspects, the angular rail mount includes a first fastening member connected to the equipment rail and a second fastening member adapted to connect to the cabinet distribution equipment. The second fastening member is angularly offset from the first fastening member to have a virtual plane defined by the second fastening member intersecting virtual orthogonal planes of the cabinet frame. That is, the angular rail mount positions the cabinet distribution equipment offset from the rails that define the cabinet system. In some aspects, the cabinet system of the present disclosure provides angular adjustability to the cabinet distribution equipment providing improved utilization and the adaptability of the space within the cabinet system.

The computing equipment being stored may include, but is not limited to, computer processing drives, storage devices, or communication network devices.

The cabinet distribution equipment may include but is not limited to a power distribution unit (PDUs) (e.g., power strip), fluid manifolds (e.g., a supply fluid manifold and/or a return fluid manifold for direct-to-chip liquid cooling), among others. In some implementations, the cabinet distribution equipment may extend longitudinally in the interior space (e.g., cabinet distribution equipment may have a longitudinal axis parallel to the cabinet frame).

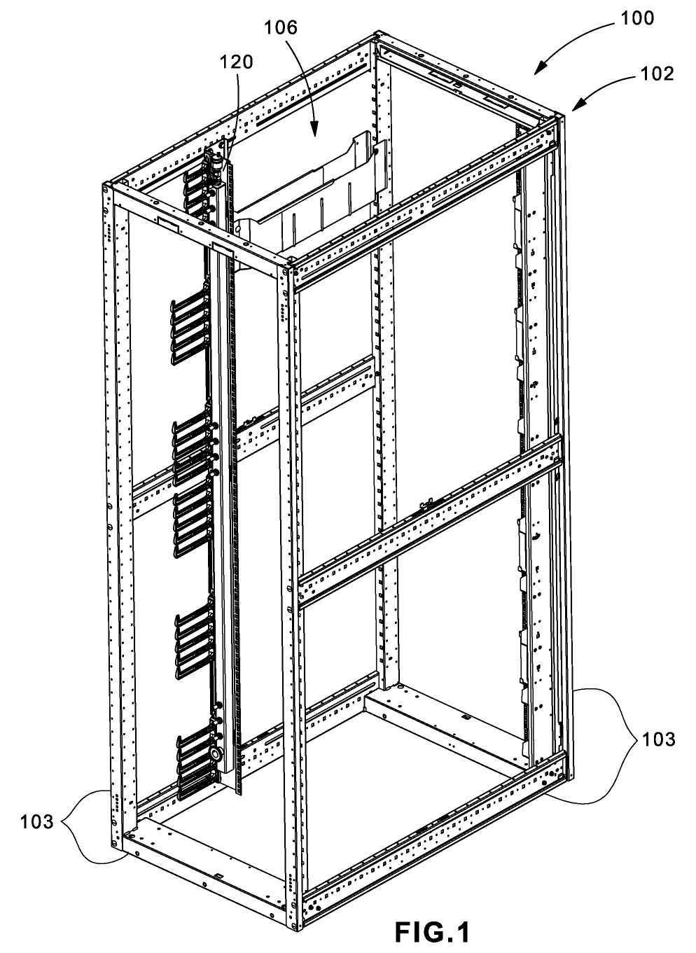

Referring to FIGS. 1, 2A, 2B, 3, 4A, and 4B, in a first embodiment, a cabinet system 100 includes a cabinet frame 102 and an equipment rail (e-rail) 104. The cabinet frame 102 includes a plurality of rails 103 that define an interior space 106. The cabinet system 100 further includes an angular rail mount 108 for connecting a cabinet distribution equipment 110 to the e-rail 104 and providing angular adjustability of the cabinet distribution equipment 110. In a non-limiting example, the cabinet distribution equipment 110 is provided as DTC manifolds (DTC manifold 110) that is mounted to the e-rail 104 via the angular rail mount 108. The cabinet system 100 may include other components, such as, but not limited to a front-to-back cable trough 111 for holding cables.

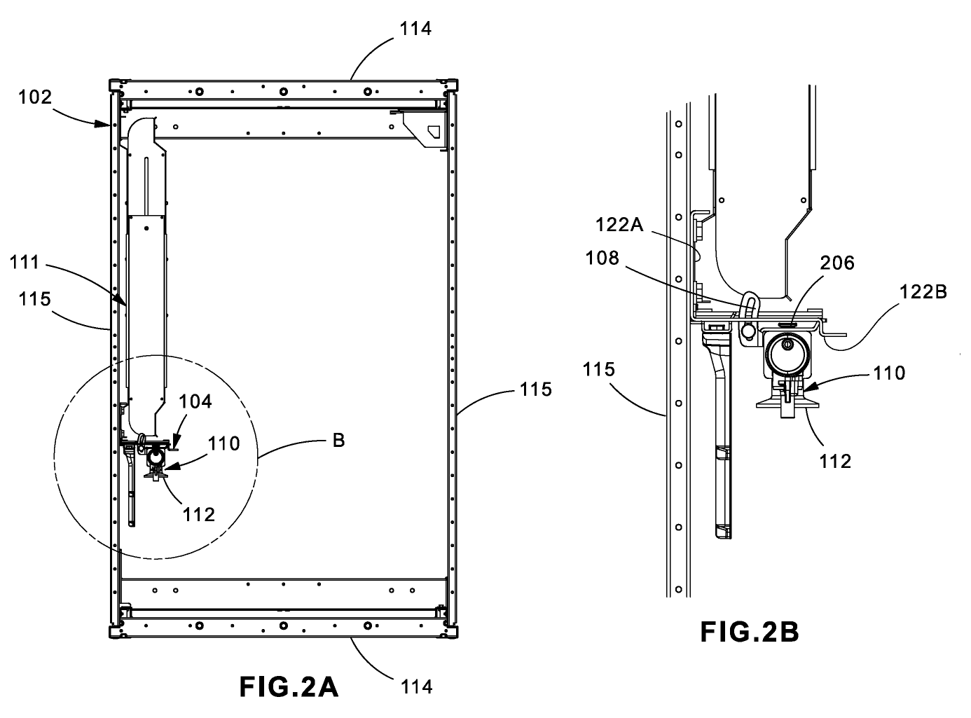

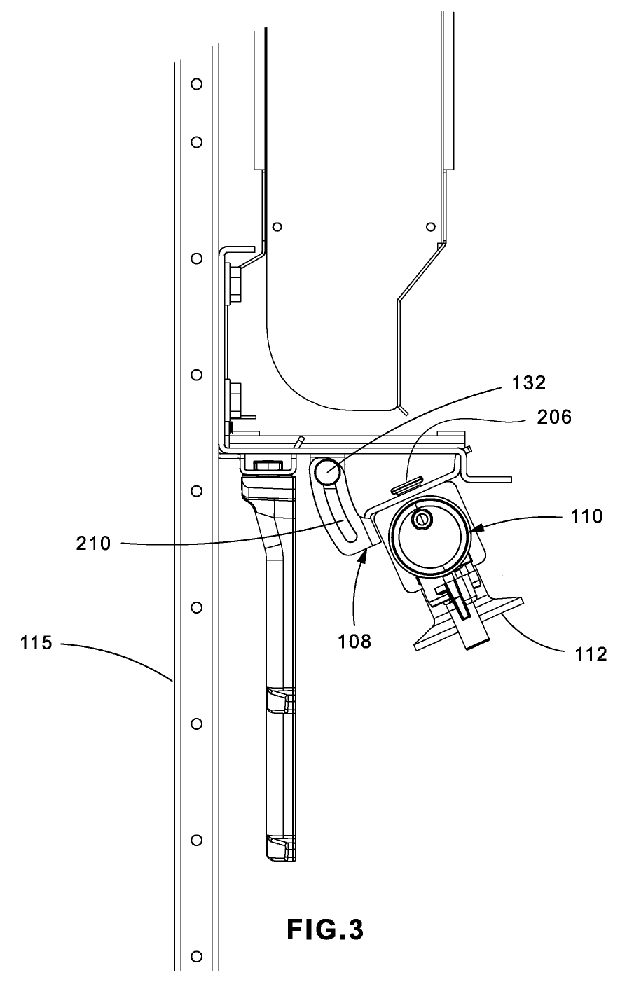

In FIG. 2B, the angular rail mount 108 is set to a zero offset position to have the manifold 110 at a zero angular adjustment. That is, a front surface 112 of the manifold 110 is parallel with lateral sides 114 of the cabinet frame 102 and perpendicular to longitudinal depth sides 115. In FIG. 3, the angular rail mount 108 provides an angular offset to have the manifold 110 directed inwardly, or stated differently, to have the front surface 112 of the manifold 110 offset and not parallel to the lateral side 114 of the cabinet frame 102.

The e-rail 104 and the angular rail mount 108 form an angularly adjustable e-rail assembly 120 for the manifold 110. In some aspects, the e-rail 104 has a first longitudinal wall 122A connected to the cabinet frame 102 and a second longitudinal wall 122B orthogonal to the first longitudinal wall 122A. The second longitudinal wall 122B extends towards the interior space 106 or, stated differently, away from the portion of the cabinet frame 102 that the first longitudinal wall 122A is connected to.

In some variations, the e-rail assembly 120 includes alternating cable management and front-to-back pass-through functionality. In a non-limiting example, the cable management feature is provided by short cable management fingers 124A and long management fingers 124B (collectively cable management fingers 124). The cable management fingers 124 are mounted to brackets 126 distributed longitudinally along the e-rail assembly 120 and attached to the e-rail 104. In a non-limiting example, the fingers 124 and the brackets 126 are attached using fasteners (e.g., screws, bolts) or without discrete fasteners by having features defined by the fingers 124 and/or the brackets 126 (e.g., keyholes defined by the bracket 126 and hooks formed with the fingers 124 that are inserted in the keyholes). The location of the cable management fingers 124 may vary and is not limited to the configuration provided in the drawings. In some variations, a group of cable management fingers 124 are provided together and separated from another group of cable management fingers 124 by a pass-through opening 128. The alternating arrangement of a group of cable management fingers 124 and a pass-through opening 128 provides cable management and pass-through functionality at all vertical levels of the cabinet system 100.

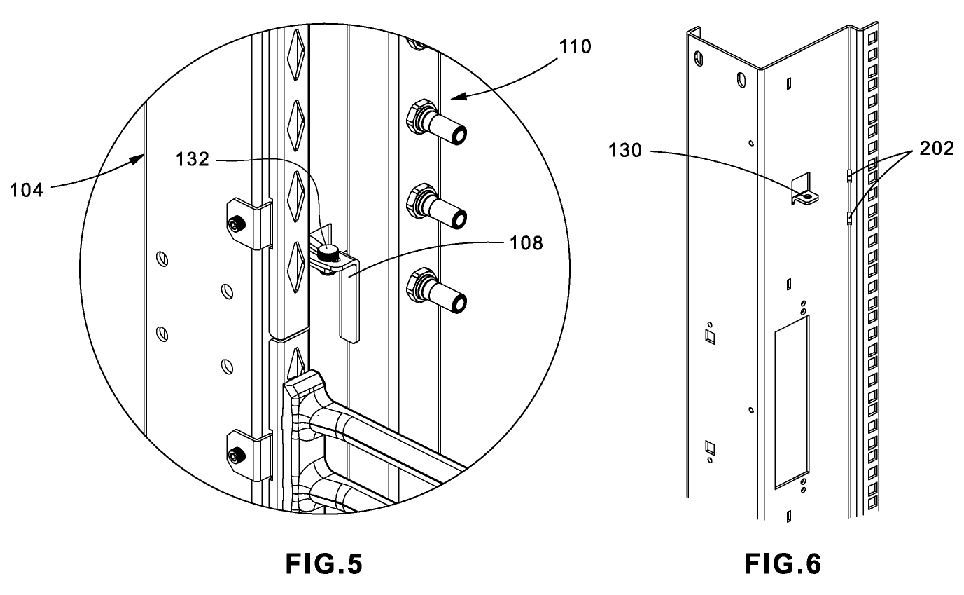

Referring to FIGS. 5 and 6, in some aspects, the e-rail 104 includes a bracket flange 130 that pivotally connects the angular rail mount 108 to the e-rail 104. In a non-limiting example, the bracket flange 130 is fastened to the angular rail mount 108 via a thumbscrew 132. Other suitable fasteners may be used such as, but not limited to, a typical wrench-driven screw.

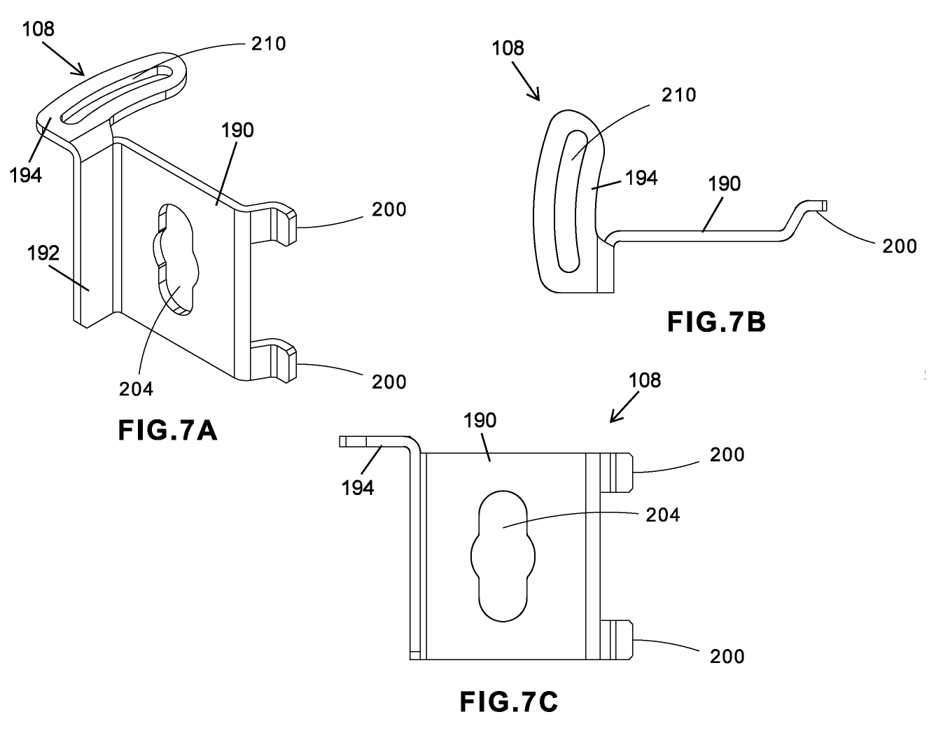

Referring to FIGS. 7A, 7B, and 7C, the angular rail mount 108 includes a body 190, a lip 192, a tab 194, and at least two fastening members, where at least one fastening member (e.g., a first fastening member) connects the angular rail mount 108 to the e-rail 104 and at least another fastening member (e.g., a second fastening member) connects the angular rail mount 108 to the manifold 110. The lip 192 may be configured to extend from the body 190 in a first direction and may be positioned perpendicular (e.g., substantially perpendicular) to the body 190. A first fastening member 200 may be configured to extend from the body 190 in a second direction opposite the first direction, and the first fastening member 200 may be positioned perpendicular (e.g., substantially perpendicular) to the body 190. In some aspects, the first fastening member includes one or more pivot tabs 200 that are inserted into notches 202 or, stated differently, slots, of the e-rail 104 (FIG. 6). The notches 202 provide a pivot point for the tabs 200 to pivot around and retain the angular rail mount 108 to the e-rail 104. The second fastening member includes a keyhole 204 that connects with a mounting button 206 on the manifold 110 to retain or hold the manifold 110 (the mounting button 206 is illustrated in FIG. 2B and 3). The second fastening member may be formed within the body 190. For example, the second fastening member may be positioned along a central axis of the body 190. In the following, the first fastening member is referred to as a “first fastening member 200” and the second fastening member may be referred to as a “second fastening member 204.”

With continuous reference to FIGS. 7A, 7B, and 7C, the dynamic angular range of the angular rail mount 108 is provided by a groove 210 or, stated differently, a radial slot. The groove 210 may be formed in the tab 194. The tab 194 may extend from the lip 192 and may be positioned perpendicular to the lip 192 and/or the body 190. For example, the lip 192 and the tab 194 may form a right angle. The groove 210 may be pivotably coupled to the e-rail 104 via the bracket 130. For example, when the thumbscrew 132 is in a loosened state, the groove 210 may slide along a shaft of the screw 132. Once the desired angular position is reached, the thumbscrew 132 may be tightened and the angular position of the angular rail mount 108 and thus, the manifold 110 are locked in place. The groove 210 may be referred to as a third fastening member to connect the angular rail mount 108 to the e-rail 104.

With the angular rail mount 108 angularly offsetting the manifold 110, the second fastening member 204 is angularly offset from the first fastening member 200 to have a virtual plane defined by the second fastening member 204 intersecting virtual orthogonal planes of the cabinet frame 102. That is, referring to FIGS. 2A, 2B, and 3, the second fastening member 204 defines a virtual plane that is parallel to a virtual plane defined by the front surface 112 of the manifold 110. The cabinet frame 102, having a rectangular cross-section, defines orthogonal planes via adjacent pair of sides 114, 115. With zero offset, the virtual plane defined by the second fastening member 204 is parallel to the lateral sides 114 of the cabinet frame 102. With an angular offset, the virtual plane of the second fastening member 204 is no longer parallel to the sides 114 and intersects the planes formed by the sides 114 and even, the orthogonal planes of adjacent pair of sides 114, 115.

In an example implementation, the angular rail mount 108 is provided as a singular discrete component having the first fastening member 200, the second fastening member 204, and the third fastening member 210. As described below, the angular rail mount may include multiple components attached to each other.

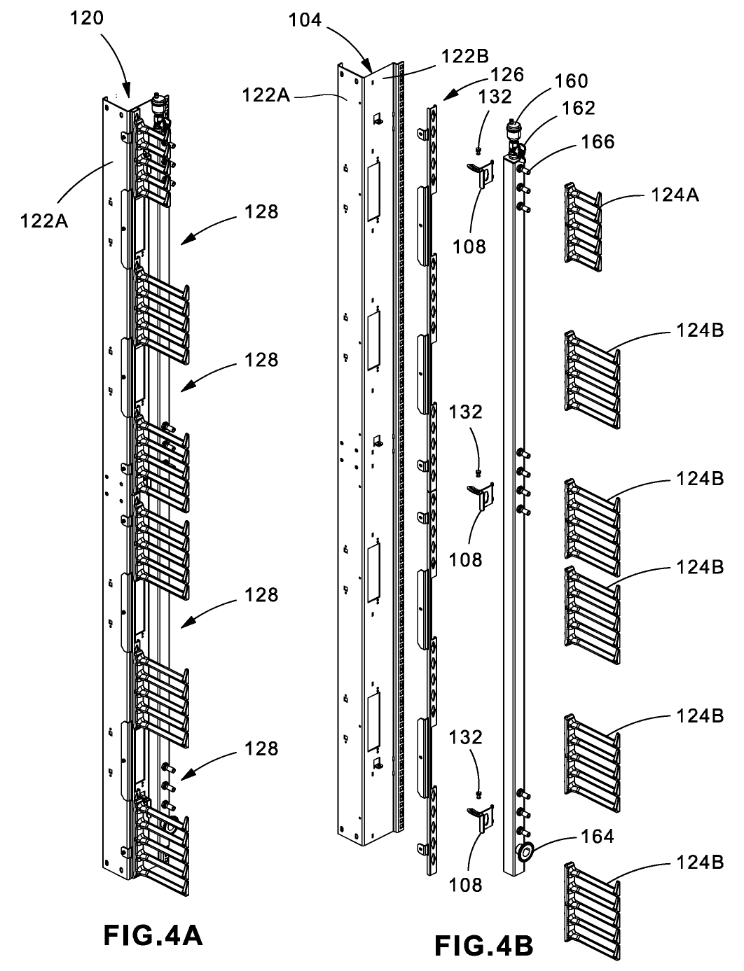

Continuous reference to FIGS. 4A, 4B, and 5, an example implementation of the manifold 110 is provided. The manifold 110 is mounted to multiple angular rail mounts 108 along a longitudinal axis of the manifold 110. In a non-limiting example, the manifold 110 includes auto vent valve 160, ball valve 162, and sanitary flange 164. The manifold 110 also includes disconnect fitting plug 166.

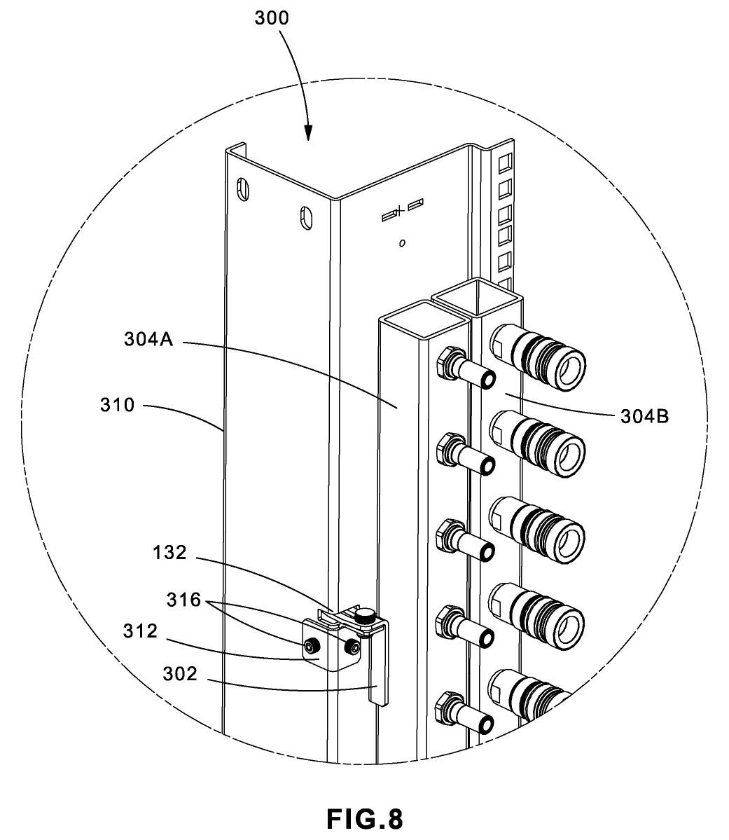

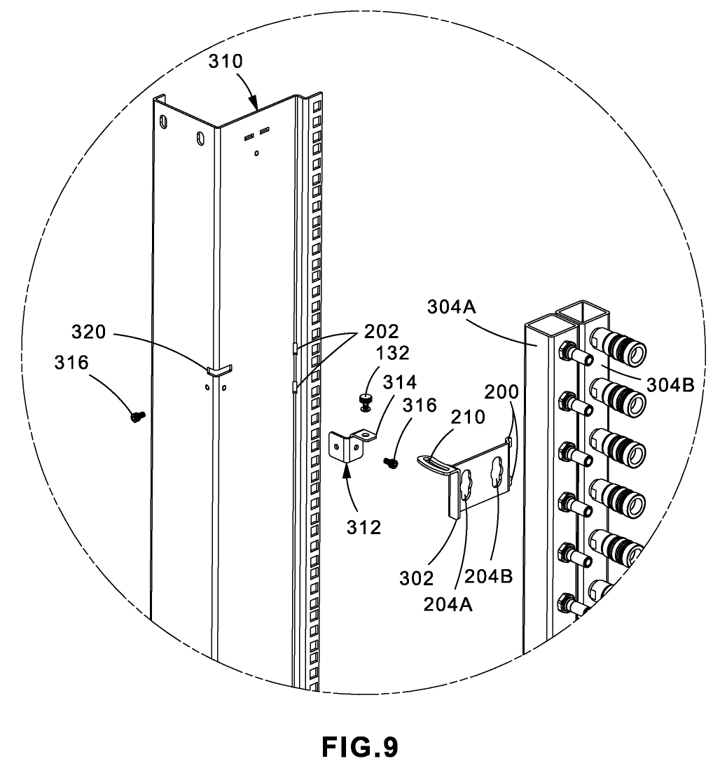

Referring to FIGS. 8 and 9, in a second embodiment, an e-rail assembly 300 is similar to e-rail assembly 120, but the e-rail assembly 300 includes an angular rail mount 302 adapted to connect to multiple cabinet distribution equipment (e.g., manifolds 304A, 304B, collectively manifold 304). Like mount 108, the angular rail mount 302 includes the groove 210 and tabs 200. In lieu of one keyhole 204, the angular rail mount 302 includes a keyhole 204A, 204B for each manifold 304 (e.g., two keyholes 204). In an example implementation, the keyhole 204A connects to the mounting button of the manifold 304A and the keyhole 204B connects to the mounting button of the manifold 304B.

The manifold 304A may be a supply manifold and the manifold 304B is a return manifold. It should be readily understood that the multiple cabinet distribution equipment may be the same type of device or different devices and should not be limited to the example provided herein.

Another difference in the e-rail assembly 300 is in the bracket flange 130 of the e-rail 104. Specifically, the e-rail assembly 300 of FIGS. 8 and 9 includes an e-rail 310 that includes notches 202 for the tabs 200 like the e-rail 104 of FIGS. 1, 2A, 2B, 3, 4A, and 4B. In lieu of a built-in bracket flange 130 of the e-rail 104, a bolt-on bracket 312 having a bracket flange 314 is connected to the e-rail 310 using fasteners 316 (e.g., bolts). The groove 210 of the angular rail mount 302 is slidably connected to the bracket flange 312 using thumbscrew 132. The e-rail 310 further defines a clearance window 320, which allows the groove 210 of the angular rail mount 302 to pass through as the groove 210 slide or rotates about the thumbscrew 132.

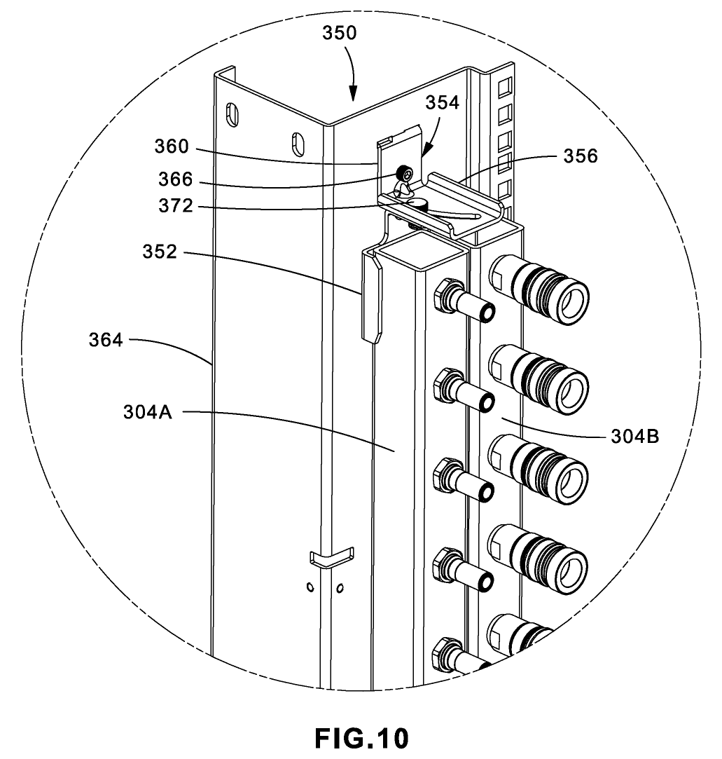

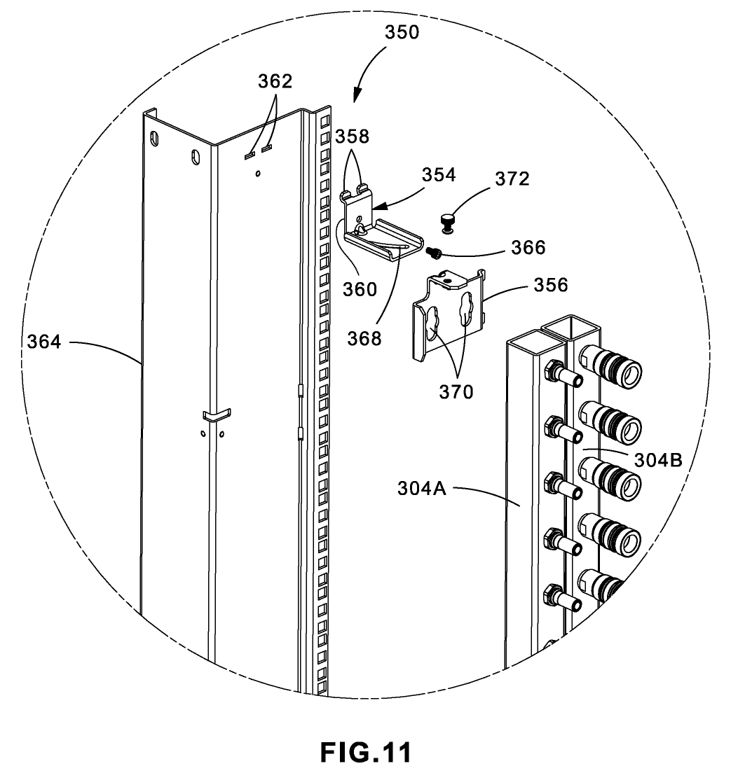

Referring to FIGS. 10 and 11, in a third embodiment, an e-rail assembly 350 includes an angular rail mount 352 that connects to the multiple cabinet distribution equipment 304 (e.g., two manifolds 304A, 304B) and moves the cabinet distribution equipment 304 at the ends of the equipment 304 instead of at the sides. Specifically, the angular rail mount 352 includes an end mount 354 and adjustable angle bracket 356. The end mount 354 includes, as the first fastening member, tabs 358 that is disposed in notches 362 defined by the e-rail 364 and a bolt-in bracket 360 that is fastened to the e-rail 364 via a bolt 366. The end mount 354 further includes a groove 368 that is similar to the grooves 210 for sliding or rotating the manifolds 304. The adjustable angle bracket 356 includes keyholes 370, as the second fastening mechanism, to connect to the manifolds 304A, 304B via mounting buttons (not shown). The adjustable angle bracket 356 is rotatably connected to the end mount 354 via the thumbscrew 372. The method for adjusting and locking the manifold is the same as first and second embodiments. While two cabinet distribution equipment 304 are illustrated, the angular rail mount 352 may be adapted for one or more cabinet distribution equipment. In addition, the angular rail mount 352 may be connected at both ends of the manifolds 304.

By having the angular rail mount 352, the connection and rotation of the cabinet distribution equipment(s) is at the ends where there is typically more space and provides space for additional cabinet features such as cable management devices or front to back pass through openings.

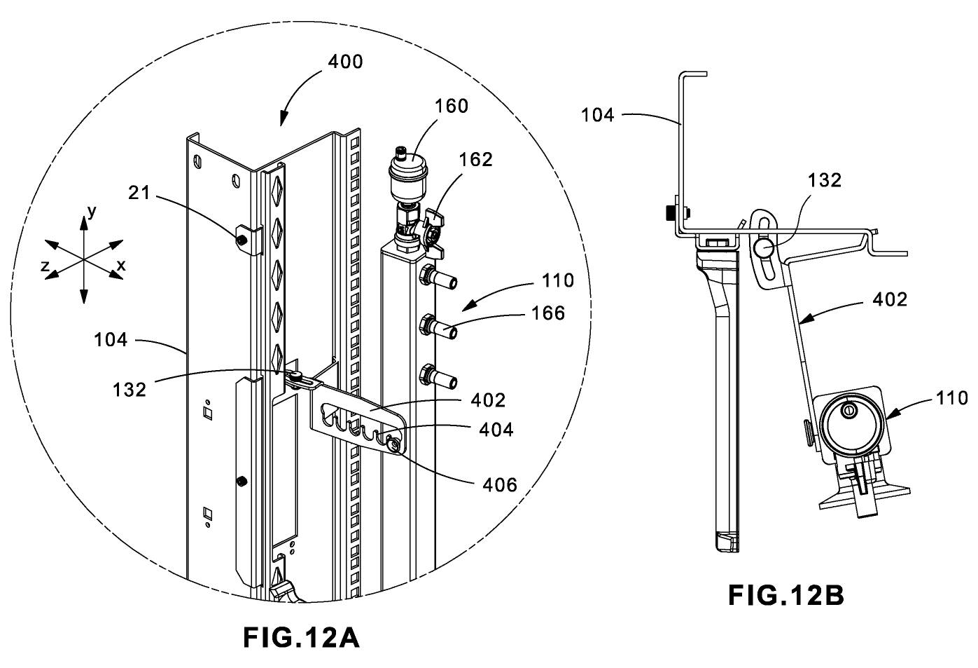

Referring to FIGS. 12A and 12B, in a fourth embodiment, an e-rail assembly 400 is similar to the e-rail assembly 120 of the first embodiment. But the e-rail assembly 400 is configured to allow positional adjustments along the longitudinal axis (e.g., y-axis) and/or forward-back directions (e.g., x-axis). Specifically, the e-rail assembly 400 includes an angular rail mount 402 that is similar to the angular rail mount 108 by having, at least, the groove 210 to rotate the manifold 110 and tabs 200 to connect to the e-rail 104. In lieu of the keyhole 204, the angular rail mount 402 includes a varying keyhole 404 defining multiple apertures having different positions along the y- and x- axes for mounting the manifold 110. In a non-limiting example, the keyhole 404 is defined to adjust position of the manifold 110 longitudinally in 15 millimeter (mm) increments. The manifold 110 is positioned into the desired keyhole location using the mounting buttons 406 provided on the side of the manifold 110.

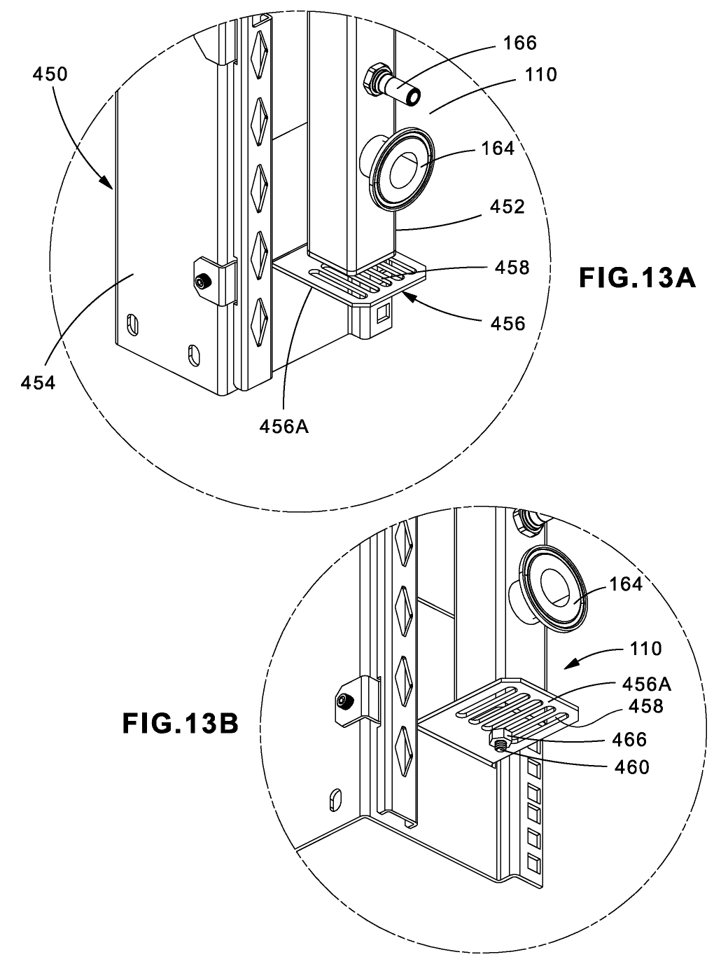

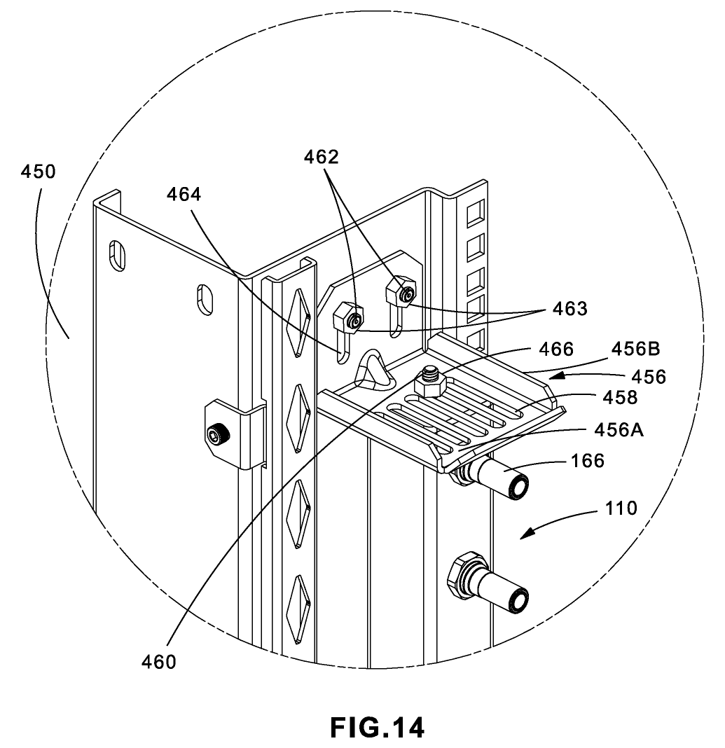

Referring to FIGS. 13A, 13B, and 14, in a fifth embodiment, an e-rail assembly 450 provides both angular and longitudinal adjustments to a manifold 452 using an e-rail 454 that secures at the ends of the manifold 110. Specifically, the e-rail 454 includes an angular rail mount 456 having a lower mount 456A and an upper mount 456B. The lower mount 456A and the upper mount 456B both have flat surfaces that are parallel to the ground and contain numerous mounting slots 458 that run along the length of the mount 456A, 456B. The slots 458 receive studs 460, which are secured (e.g., welded) at the ends of the manifold 110. The studs 460 slide along the slot 458 to a desired lateral position and the manifold 110 may be adjusted angularly (e.g., rotated) within the selected slot 458.

In one form, the lower mount 456A is part of the e-rail 454 and the upper mount 456B includes, as a first fastening mechanism, to attach to the e-rail 454 via bolts 462 and nuts 463. The upper mount 456B defines longitudinal holes 464 to allow longitudinal adjustment of the angular rail mount 456 and, thus, the manifold 110. The upper mount 456B is able to slide up and down to provide clearance for the manifold 110 upon installation. In a non-limiting example, to install the manifold 110, the manifold 110 is placed on the lower mount 456A, which is fixed, and the upper mount 456B is moved, if needed, up to clear the manifold 110. Once positioned, the upper mount 456B is positioned over the manifold 110 to have the stud 460 extend through the slot 458.

Once the manifold 110 is set to a desired longitudinal, lateral, and/or angular position, nuts 466 are tightened on the studs 460 providing friction between angular rail mount 456 and the manifold 452. In addition, the bolts 462 on the upper mount 456B are tightened via the nuts 463 to lock the upper mount 456B.

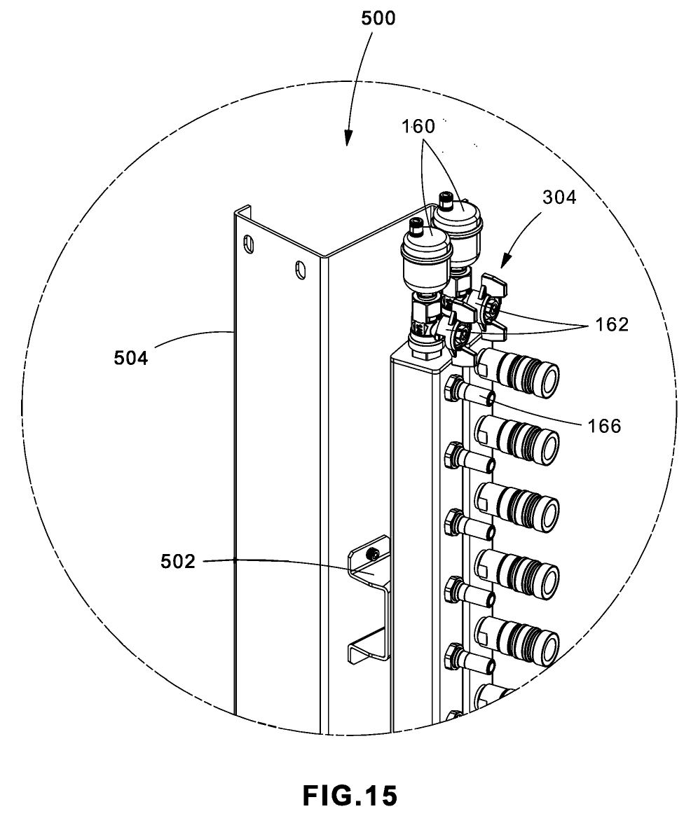

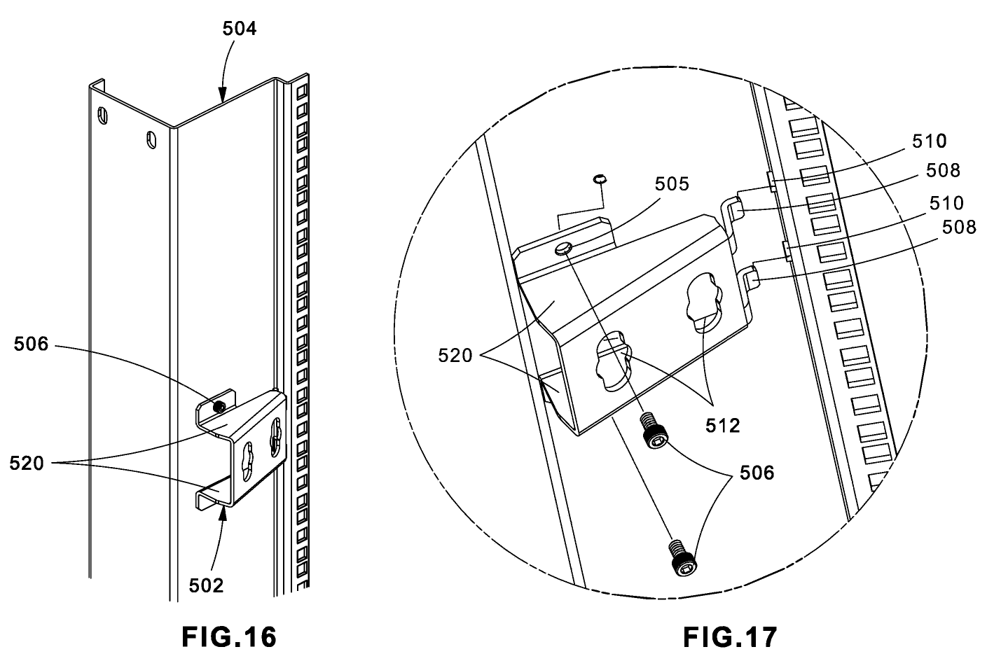

Referring to FIGS. 15-20, in a sixth embodiment, an e-rail assembly 500 includes an angular rail mount 502 that secures multiple manifolds 304 to an e-rail 504 at a fixed-angle, and may be referred to as a static angular rail mount, whereas the angular rail mounts of the first to fifth embodiments may be considered dynamic or adjustable angular rail mounts.

The static angular rail mount 502 defines fastening holes 505 for screws 506 to secure the mount 502 to the e-rail 504. The static angular rail mount 502 further includes tabs 508 that are arranged in notches 510 defined in the e-rail 504. The tabs 508 and/or the holes 505 form first

fastening member. The tabs 508 anchors the static angular rail mount 502 to the e-rail 504 at one end and the other end is anchored via the holes 505 and screws 506.

The static angular rail mount 502 further defines keyholes 512, as a second fastening member, for each manifold 304. The figures only show one static angular rail mount 502, but multiple mounts 502 may be disposed longitudinally along the e-rail (e.g., top, middle, and bottom). While the static angular rail mount 502 has multiple keyholes 512 for multiple manifolds 304, the static angular rail mount 502 may include one or more keyholes based on the number of manifolds to be attached.

The static angular rail mount 502 includes a lateral member 520 connecting a flange defining the holes 505 (e.g., first fastening member) to a flange defining the keyholes 512 (e.g., the second fastening member) defining tapered body. The lateral member 520 is adapted to control distance between the second fastening member and the first fastening member and to control position of the second fastening member within the interior space of the cabinet system.

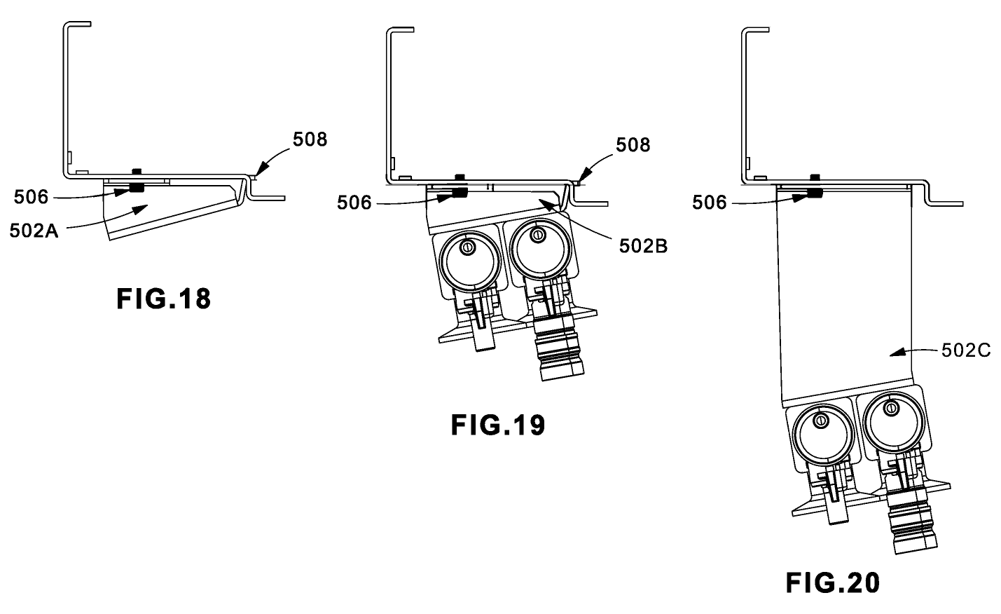

In some implementations, an assortment of static angular mounts having different fixed-angles can be provided. The user may install the set of static angular mounts to the e-rail 504 that corresponds with a desired angle for the manifold 304. FIGS. 18-20 provide static angular mounts 502A, 502B, and 502C having different fixed angles. The mount 502A defines a larger fixed-angle than the mount 502B. The mount 502C moves the manifolds 304 rearward in the cabinet system. This may be desirable by certain users and in certain cabinet configurations.

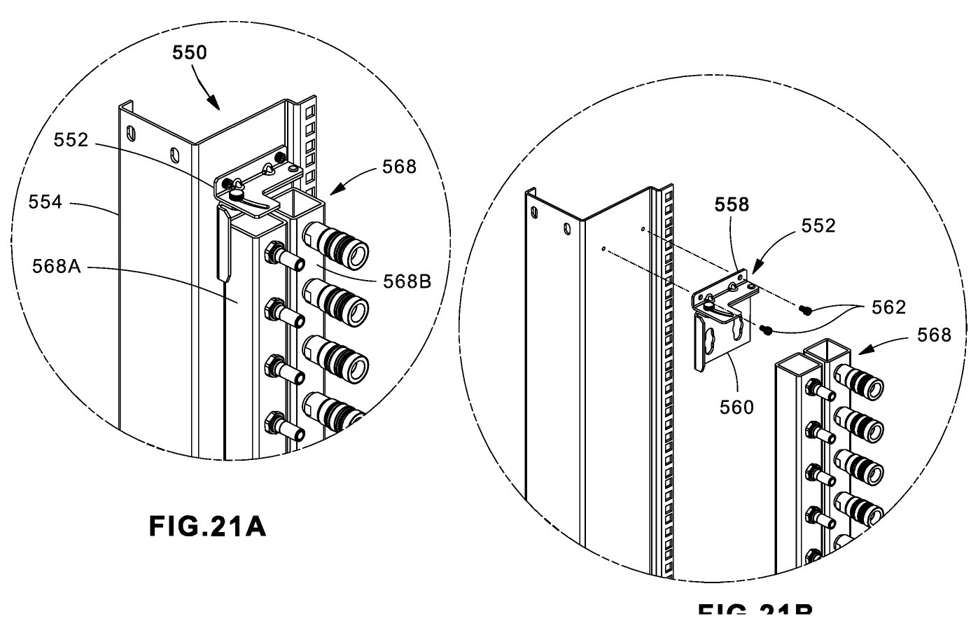

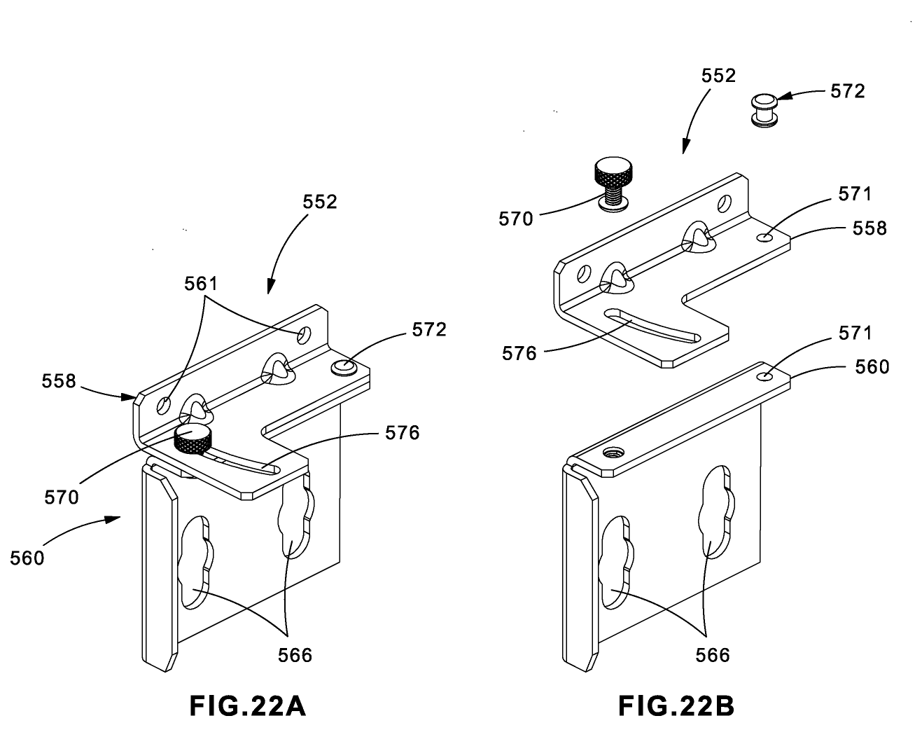

Referring to FIGS. 21A, 21B, 22A, and 22C, in a seventh embodiment, an e-rail assembly 550 includes angular rail mount 552 that has a standalone fastening mechanism to secure to an e-rail 554. The angular rail mount 552 is similar to the angular rail mount 352 of FIGS. 10 and 11, but does not include the tabs. Accordingly, the e-rail 554 does not need a special features, such as notches. The angular rail mounts 552 are assembled and operate independently of the e-rail 554. In this embodiment, the angular rail mounts 552 may be assembled as a standalone subassembly, independent of the e-rail 554.

In some aspects, the angular rail mount 552 includes an end mount 558 and adjustable angle bracket 560. The end mount 558, having the first fastening member, defines holes 561 to receive screws 562 to connect the angular rail mount 552 to the e-rail 554. The adjustable angle bracket 560 includes keyholes 566, as the second fastening mechanism, to connect to the manifolds 568 (manifolds 568A, 568B) via mounting buttons (not shown). The adjustable angle bracket 560 is connected to the end mount 354 via a thumbscrew 570 and pin 572.

The end mount 558 is fastened to the e-rail 554, creating a mounting system between manifolds 568 and the e-rail 554. The pin 572 and thumbscrew 570 facilitate rotation between the end mount 558 and adjustable angle bracket 560. The pin 572 is inserted into aligning holes 571 on each end mount 558 and adjustable angle bracket 560 to provide touch-alignment. The adjustable angle bracket 560 is free to rotate around the pin 572. A groove 576 rides along the shank of thumbscrew 570 and provides a limit on the angular travel of adjustable angle bracket 560. Similar to the other embodiments having the thumbscrew, the thumbscrew 570 is also used to lock the desired angle or angular offset. In some variations, the end of the shank of thumbscrew 570 is peened after the upper and lower brackets are assembled in production. This prevents the user from over-loosening thumbscrew 570, which could allow it to fall out of the assembly.

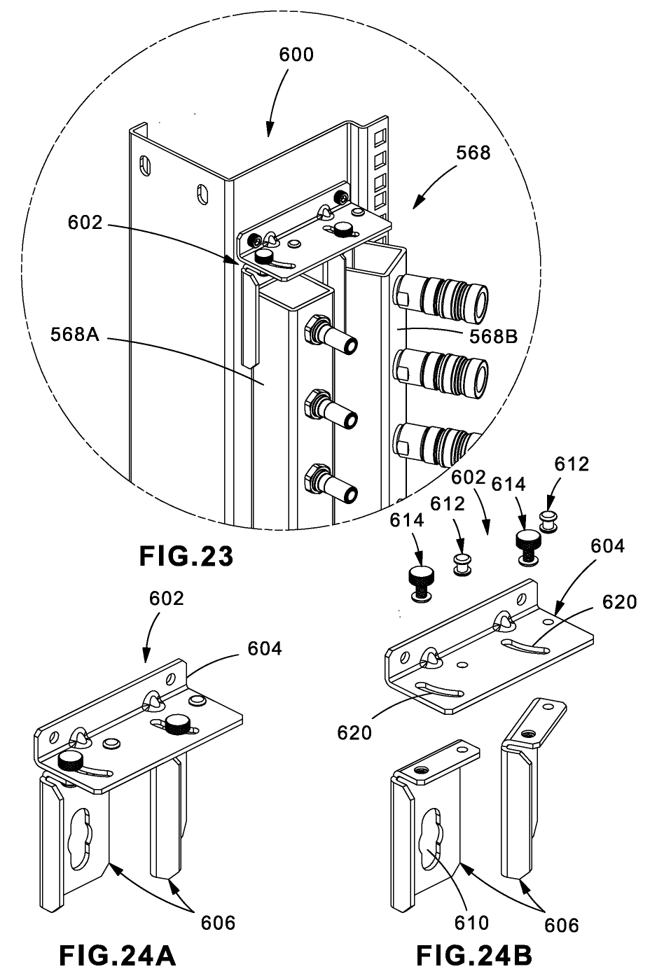

Referring to FIGS. 23, 24A, and 24B, in an eighth embodiment, an e-rail system 600 includes an angular rail mount 602 which is similar to angular rail mount 552 of FIGS. 21A, 21B, 22A, and 22C, because it is a standalone angular rail mount. At least one distinction is that the angular rail mount 602 allows for independent angular adjustment of the two-manifolds 568, such that one manifold may be positioned at a different angular offset than the other manifold.

In some aspects, the angular rail mount 602 includes an end mount 604 and one adjustable angle bracket 606 for each manifold 568. The adjustable angle bracket 606 defines single keyhole 610 to connect to a single manifold 568. Both adjustable angle brackets 606 are fastened to the end mount 604 via pins 612 and thumbscrews 614.

Like the seventh embodiment, the pins 612 and thumbscrews 614 facilitate rotation between the end mount 604 and the adjustable angle brackets 606. The pins 612 are inserted into aligning holes on the end mount 604 and adjustable angle brackets 606. The adjustable angle brackets 606 are free to rotate around pins 612. Radial grooves 620 defined at the end mount 604 ride along the shanks of thumbscrews 614 and provide a limit on the angular travel of the adjustable angle brackets 606. Thumbscrews 614 are also used to lock the desired angle of adjustment into place.

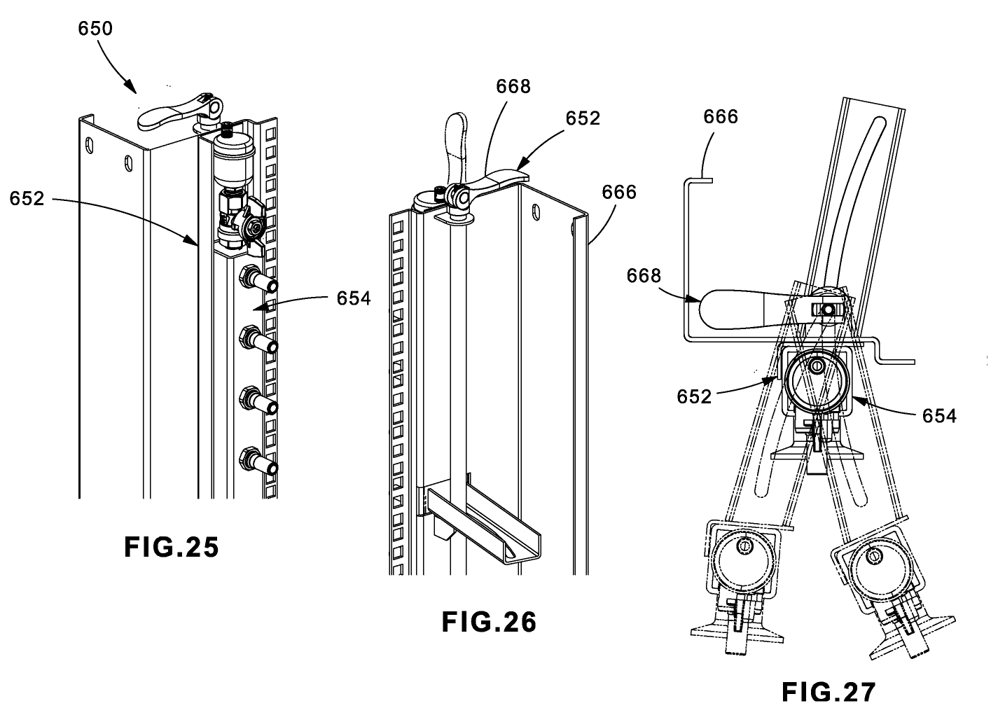

Referring to FIGS. 25 to 27, in a ninth embodiment, an e-rail assembly 650 allows for infinite adjustment within a given range without the need for tools. The e-rail assembly 650 includes a manifold carrier assembly 652 connected to a manifold 654 using mounting buttons like previous embodiments. The manifold carrier assembly 652 is connected to an e-rail 666 using a clamping mechanism 668, such as over-center cam clamp. FIG. 27 is a top view showing a possible range of motion achievable with the mechanism 668.

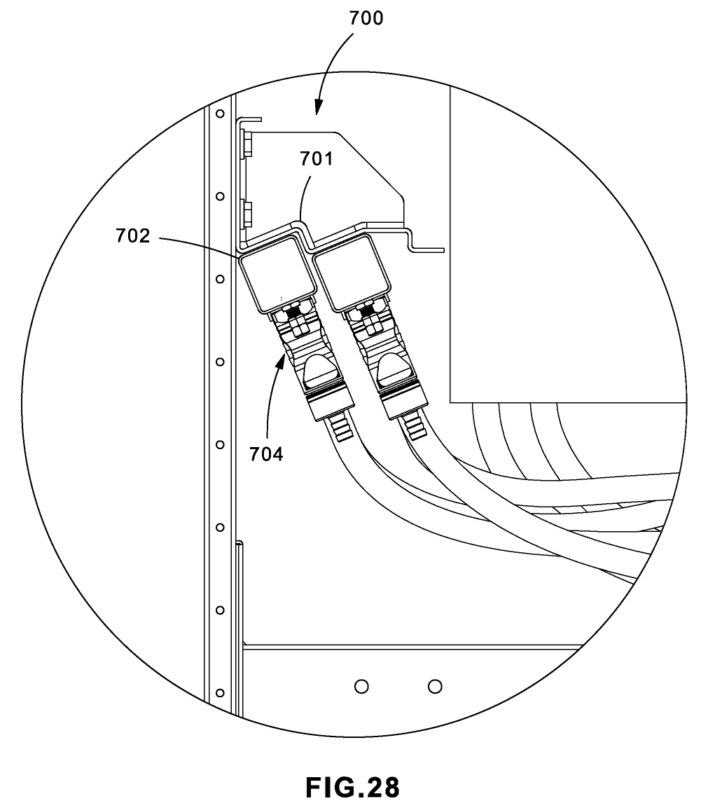

Referring to FIG. 28, in a tenth embodiment, an e-rail assembly 700 includes an angled e-rail 701 and an angled rail mount 702 having fixed angle. In this system, the angled rail mount 702 is designed to have two angled surfaces, each of which mounts a manifold 704. Each surface contains a pair of keyhole feature (not shown) which facilitates mounting via the mounting buttons on the manifolds 704. The e-rail 701 and the angled rail mount 702 can be designed to accommodate manifolds 704 at any angle.

While the present disclosure describes specific fastening components (e.g., bolt, screw, nut, thumbscrew, etc.), it should be understood that any suitable fastening components may be used based on the connection to be achieved.

While the present disclosure illustrates specific shapes for the keyhole used to attach to the manifold, it should be understood that the keyhole may be provided in any suitable shapes.

While the e-rail assembly having the e-rail and the angular rail mounts is described with respect to a cabinet system, it should be understood that the e-rail assembly may also be used with a rack.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A cabinet system, comprising:
a cabinet frame including a plurality of rails defining an interior space to house computing equipment;
an equipment rail connected to the cabinet frame in the interior space and extending parallel to a longitudinal axis of the cabinet frame; and
an angular rail mount including a first fastening member connected to the equipment rail and a second fastening member adapted to connect to a cabinet distribution equipment, the second fastening member being angularly offset from the first fastening member to have a virtual plane defined by the second fastening member intersecting virtual orthogonal planes of the cabinet frame.

2. The cabinet system of claim 1, wherein the equipment rail includes a first wall connected to the cabinet frame and a second wall orthogonal to the first wall and extending toward the interior space, and the first fastening member of the angular rail mount is connected to the second wall of the equipment rail.

3. The cabinet system of claim 2, further comprising a plurality of fasteners to fasten the first fastening member to the second wall.

4. The cabinet system of claim 1, wherein the angular rail mount includes a third fastening member defining a groove pivotably connected to the equipment rail to change the angular offset of the second fastening member.

5. The cabinet system of claim 4, wherein the angular rail mount is a singular discrete component having the first fastening member, the second fastening member, and the third fastening member.

6. The cabinet system of claim 1, wherein the equipment rail defines a plurality of notches along the longitudinal axis of the equipment rail, and the angular rail mount includes multiple tabs, as the first fastening member, attachable to a set of notches among the plurality of notches of the equipment rail.

7. The cabinet system of claim 1, the angular rail mount defines a plurality of keyholes to connect to a plurality of the cabinet distribution equipment.

8. The cabinet system of claim 1, wherein the angular rail mount includes a lateral member connecting the first fastening member and the second fastening member, the lateral member is adapted to control distance between the second fastening member and the first fastening member and to control position of the second fastening member within the interior space.

9. A cabinet system, comprising:
a cabinet frame comprising a plurality of rails;
an equipment rail connected to a rail of the plurality of rails; and
an angular rail mount rotatably coupled a manifold to the equipment rail, wherein the angular rail mount comprises:
a first fastening member connected to the equipment rail;
a second fastening member connected to the manifold; and
a third fastening member rotatably coupled to the equipment rail to adjust an angular offset of the second fastening member with respect to the equipment rail.

10. The cabinet system of claim 9, wherein the angular rail mount comprises:
a body; and
a lip extending from the body in a first direction, wherein the first fastening member extends from the body in a second direction opposite the first direction.

11. The cabinet system of claim 10, wherein the angular rail mount comprises a tab extending from the lip, wherein the third fastening member is formed within the tab.

12. The cabinet system of claim 11, wherein the lip is positioned perpendicular to the body.

13. The cabinet system of claim 10, wherein the second fastening member is formed within the body.

14. The cabinet system of claim 9, wherein the equipment rail comprises a plurality of notches, wherein at least one notch of the plurality of notches receives the first fastening member.
